(19) United States
(12) Patent Application Publication
(10) Pub. No.: US 2018/0327541 A1
(43) Pub. Date: Nov. 15, 2018

(54) THERMOSETTING RESIN COMPOSITION, CURED PRODUCT OBTAINED THEREFROM, AND ACTIVE ESTER RESIN FOR USE THEREIN

(71) Applicant: DIC Corporation, Tokyo (JP)

(72) Inventors: Kazuo Arita, Ichihara-shi (JP); Tatsuya Okamoto, Ichihara-shi (JP)

(73) Assignee: DIC Corporation, Tokyo (JP)

(21) Appl. No.: 15/527,876

(22) PCT Filed: Nov. 10, 2015
(86) PCT No.: PCT/JP2015/081574

§ 371 Date: May 18, 2017

(30) Foreign Application Priority Data
Dec. 15, 2014 (JP) 2014-252897

(51) Int. Cl. C08G 59/40; C08G 63/197; H05K 1/03

(52) U.S. Cl. CPC C08G 59/40; H01L 23/295; H05K 1/0373; C08G 63/197

(57) ABSTRACT

Provided are a thermosetting resin composition whose cured product exhibits a low dielectric constant and a low loss tangent as well as excellent flame retardancy, heat resistance, and thermal decomposition resistance, a cured product obtained from the thermosetting resin composition, and an active ester resin for use in the thermosetting resin composition. Specifically, the thermosetting resin composition contains, as essential components, an epoxy resin and an active ester resin having a resin structure that has a structural segment represented by formula (I) below and monovalent aryloxy groups at both terminals:

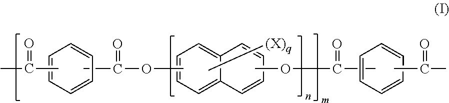

### TECHNICAL FIELD

The present invention relates to a thermosetting resin composition whose cured product exhibits excellent flame retardancy, heat resistance, low dielectric constant, low loss tangent, and thermal decomposition resistance, a cured product obtained from the thermosetting resin composition, and an active ester resin for use in the thermosetting resin composition.

### BACKGROUND ART

Thermosetting resin compositions that contain an epoxy resin and a curing agent therefor as essential components are widely used in electronic parts usages such as in semiconductors, multilayer printed boards, etc., since a cured product thereof exhibits excellent heat resistance and an excellent insulating property.

Among the electronic parts usages, the technical field of multilayer printed board insulating materials has recently seen advancement towards higher signal speeds and higher frequencies. However, as the signal speed and the frequency increase, it has become increasingly difficult to obtain a low loss tangent while maintaining a sufficiently low dielectric constant.

A thermosetting resin composition from which a cured product that exhibits a sufficiently low loss tangent while maintaining a sufficiently low dielectric constant for higher speed, higher frequency signals is obtained is highly anticipated. An active ester compound obtained by aryl-esterification of phenolic hydroxyl groups in a phenol novolac resin is known to be a material that can realise a low dielectric constant and a low loss tangent, and a technique of using this active ester compound as a curing agent for epoxy resins is known (PTL 1).

However, insulating materials used in the fields of the semiconductor and the multilayer printed boards must address environmental issues, such as issues related to dioxin. In recent years, demand for so-called halogen-free flame retardant systems, with which the resin itself is given a flame retarding effect without using halogen flame retarding additives has increased. There is known a technique of using, as a curing agent for epoxy resins, an ester compound prepared from a reaction product of benzyl alcohol and 2,7-dihydroxynaphthalene, isophthalic acid chloride, and benzoic acid chloride in order to obtain an epoxy resin material that has a low dielectric constant, a low loss tangent, and flame retardancy (PTL 2).

Under trends toward use of higher frequency and size reduction in electronic parts, the multilayer printed board insulating material is required to have extremely high levels of heat resistance and thermal decomposition resistance. However, when the above-mentioned ester compound prepared from the reaction product of benzyl alcohol and 2,7-dihydroxynaphthalene, isophthalic acid chloride, and benzoic acid chloride is cured, the cured product has a degraded crosslinking density due to introduction of aryl ester structures and sometimes exhibits insufficient thermal decomposition resistance.

Up to now, an insulating material suitable for use in multilayer printed board insulating materials that have a high level of flame retardancy, a low dielectric constant, a low loss tangent, high heat resistance, and high thermal decomposition resistance has not been known.

### CITATION LIST

### Patent Literature

PTL 1: Japanese Unexamined Patent Application Publication No. 7-82348

PTL 2: International Publication no. 2012/002119

### SUMMARY OF INVENTION

### Technical Problem

An object of the present invention is to provide a thermosetting resin composition whose cured product has a low dielectric constant and a low loss tangent as well as excellent flame retardancy, heat resistance, and thermal decomposition resistance, a cured product obtained from the composition, and an active ester resin for use in the composition.

### Solution to Problem

The inventors of the present invention have conducted extensive studies to achieve the object described above. It has been found that when a curing agent for epoxy resin has a naphthylene ether structure as a main skeleton and when an active ester structure segment is introduced into a terminal of the main skeleton, a cured product obtained therefrom exhibits a low dielectric constant and a low loss tangent as well as excellent flame retardancy, heat resistance, and thermal decomposition resistance. Thus, the present invention has been made.

In other words, the present invention relates to:

(1) a thermosetting resin composition that contains, as essential components, an epoxy resin and an active ester resin having a resin structure that has a structural segment represented by formula (I) and monovalent aryloxy groups at both terminals:

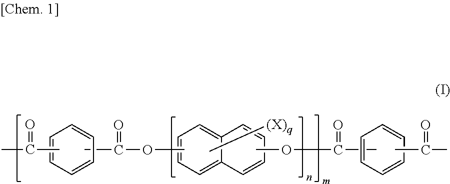

(in formula (I), X each independently represent a group represented by formula (II) below:

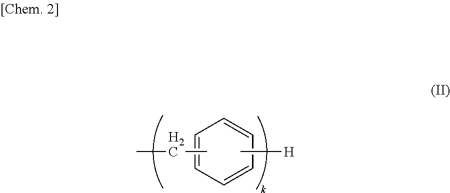

or a group represented by formula (III) below:

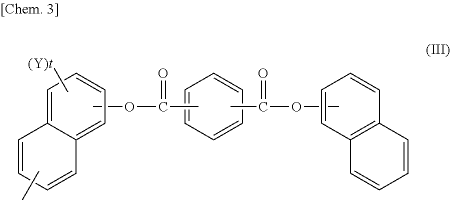

where m is an integer of 1 to 6, n each independently represent an integer of 1 to 5, and q each independently represent an integer of 0 to 6; in formula (II), k each independently represent an integer of 1 to 5; and in formula (III), Y is a group represented by formula (II) above (where k each independently represent an integer of 1 to 5), and t each independently represent an integer of 0 to 5).

(2) The present invention also relates to an active ester resin that has a resin structure that contains a structural segment represented by formula (I) below and monovalent aryloxy groups at both terminals.

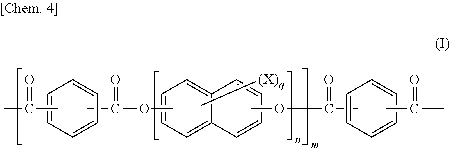

(in formula (I), X each independently represent a group represented by formula (II) below:

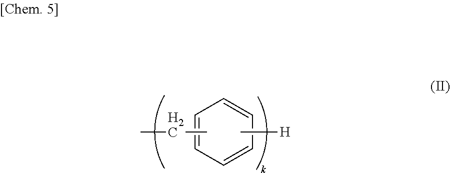

or a group represented by formula (III) below:

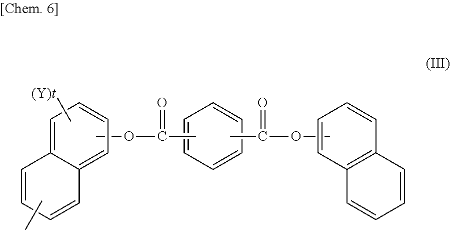

where m represents an integer of 1 to 6, n each independently represent an integer of 1 to 5, q each independently represent an integer of 0 to 6; in formula (II), k each independently represent an integer of 1 to 5; and in formula (III), Y represents a group represented by formula (II) above (where k each independently represent an integer of 1 to 5), and t each independently represent an integer of 0 to 5).

The present invention also relates to a cured product obtained by curing the thermosetting resin composition described in (1); a prepreg obtained by impregnating a reinforcing substrate with a dilution of the thermosetting resin composition described in (1) in an organic solvent and semi-curing the obtained impregnated substrate; a circuit board obtained by stacking the prepreg formed to have a plate shape and a copper foil and pressure-forming the resulting stack under heating; a buildup film obtained by applying a dilution of the thermosetting resin composition described in (1) in an organic solvent to a substrate film and drying the applied dilution; a buildup substrate obtained by applying the buildup film onto a circuit board having a circuit formed therein, curing the buildup film under heating, forming irregularities on the resulting circuit board, and plating the circuit board; a sealing material that contains the thermosetting resin composition described in (1) and an inorganic filler; and a semiconductor device obtained by curing the semiconductor sealing material under heating.

The present invention also relates to an active ester resin described in (2), obtained through a step of inducing a reaction between a dihydroxynaphthalene compound and benzyl alcohol to obtain a benzyl-modified naphthalene compound, and a step of inducing a reaction between the benzyl-modified naphthalene compound, an aromatic dicarboxylic acid chloride, and a monohydric phenol compound.

### Advantageous Effects of Invention

According to the present invention, a thermosetting resin composition whose cured product exhibits a low dielectric constant and a low loss tangent as well as excellent flame retardancy, heat resistance, and thermal decomposition resistance, a cured product of the thermosetting resin composition, an active ester resin that induces those properties, a prepreg obtained from the composition, a circuit board, a buildup film, a buildup substrate, a semiconductor sealing material, and a semiconductor device can be provided.

### BRIEF DESCRIPTION OF DRAWINGS

FIG. 1 is a GPC chart of a benzyl-modified naphthalene compound (A-2) obtained in Synthetic Example 2.

FIG. 2 is a GC-TOF-MS spectrum of the benzyl-modified naphthalene compound (A-2) obtained in Synthetic Example 2.

FIG. 3 is a GPC chart of a benzyl-modified naphthalene compound (A-3) obtained in Synthetic Example 3.

FIG. 4 is a GC-TOF-MS spectrum of the benzyl-modified naphthalene compound (A-3) obtained in Synthetic Example 3.

FIG. 5 is a GPC chart of an active ester resin (B-2) obtained in Example 2.

FIG. 6 is a MALDI-TOF-MS spectrum of the active ester resin (B-2) obtained in Example 2.

FIG. 7 is a GPC chart of an active ester resin (B-3) obtained in Example 3.

FIG. 8 is a MALDI-TOF-MS spectrum of the active ester resin (B-3) obtained in Example 3.

### DESCRIPTION OF EMBODIMENTS

The present invention will now be described in detail.

### <Active Ester Resin>

An active ester resin used in the thermosetting resin composition according to the present invention has a resin structure that has a structural segment represented by formula (I) below:

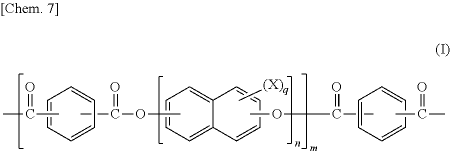

and monovalent aryloxy groups at both terminals.

(In formula (I), X each independently represent a group represented by formula (II) below:

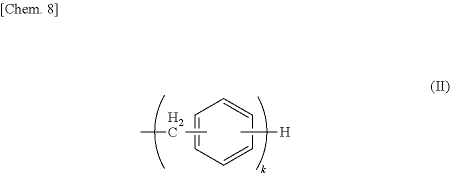

or a group represented by formula (III) below:

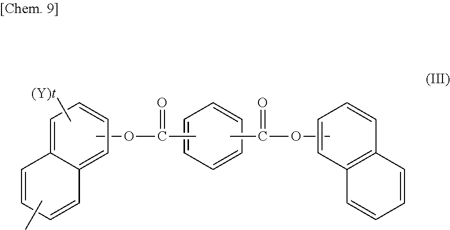

where m represents an integer of 1 to 6, n each independently represent an integer of 1 to 5, q each independently represent an integer of 0 to 6; in formula (II), k each independently represent an integer of 1 to 5; and in formula (III), Y represents a group represented by formula (II) above (where k each independently represent an integer of 1 to 5), and t each independently represent an integer of 0 to 5).

In order to clarify the relationship between m and n in formula (I), several patterns are described below; however, the active ester resin according to the present invention is not limited by these examples.

For example, when m=1, formula (I) represents a structure represented by formula (I-I) below:

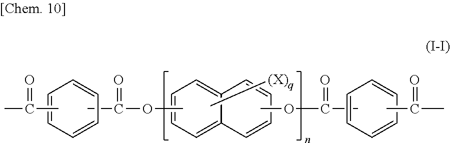

In formula (I-I), n represents an integer of 1 to 5, and q each independently represent an integer of 0 to 6. As with the relationship between m and n, with regard to q, when n is 2 or more, q each independently represent an integer of 0 to 6.

For example, when m=2, formula (I) represents a structure represented by formula (I-II) below:

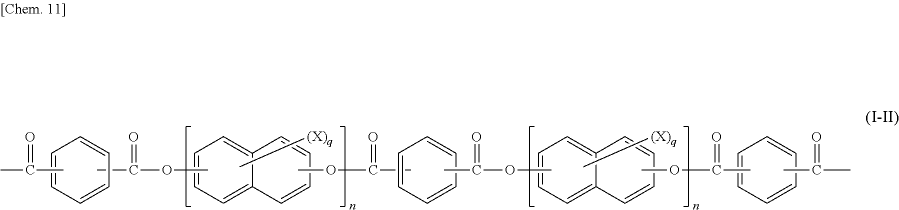

In formula (I-II), n each independently represent an integer of 1 to 5, and q each independently represent an integer of 0 to 6. As with the relationship between m and n, with regard to q, when n is 2 or more, q each independently represent an integer of 0 to 6.

### (Relationship Between the Skeleton and the Advantageous Effects)

In the present invention, the molecular main skeleton has a naphthylene ether structural segment; thus, excellent heat resistance and flame retardancy can be imparted to the cured product. Moreover, since the structural segment has a structure in which the structural segment represented by formula (IV) below serves as a bonding segment, the cured product also can exhibit excellent dielectric properties such as a low dielectric constant and a low loss tangent. Furthermore, since aryloxy groups are present at both terminals of the resin structure of the active ester resin according to the present invention, the cured product exhibits improved, sufficiently high thermal decomposition resistance for multilayer printed board usage.

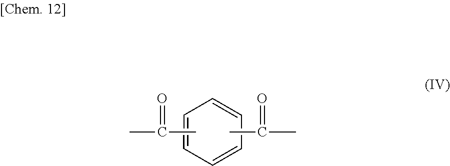

### (Softening Point)

From the viewpoint of excellent heat resistance of a cured product, the active ester resin according to the present invention preferably has a softening point within the range of 100° C. to 200° C. and more preferably within the range of 100° C. to 190° C.

In the active ester resin according to the present invention, m in formula (I) represents, for example, an integer of 1 to 6. In particular, m preferably represents an integer of 1 to 5. Furthermore, n in formula (I) represents, for example, an integer of 1 to 5. In particular, n is preferably an integer of 1 to 3.

The relationship between m and n in formula (I) is described for the record. For example, when m is an integer of 2 or more, two or more n exist, and these n each take an independent value. As long as n is within the numerical range described above, n may take the same value or different values.

In the active ester resin according to the present invention, when q in formula (I) is 1 or more, X may substitute any position in the naphthalene ring structure.

Examples of the aryloxy groups at both terminals of the resin structure include groups derived from monohydric phenol compounds, such as phenol, cresol, p-t-butylphenol (para-tertiary-butylphenol), 1-naphthol, and 2-naphthol. Among these, a phenoxy group, a tolyloxy group, or a 1-naphthyloxy group is preferable, and a 1-naphthyloxy group is more preferable from the viewpoint of thermal decomposition resistance of the cured product.

A method for producing the active ester resin according to the present invention will now be described in detail.

The method for producing an active ester resin according to the present invention includes a step of inducing a reaction between a dihydroxynaphthalene compound and benzyl alcohol in the presence of an acid catalyst to obtain a benzyl-modified naphthalene compound (A) (hereinafter this step may be described as “step 1”); and a step of inducing a reaction between the obtained benzyl-modified naphthalene compound (A), an aromatic dicarboxylic acid chloride, and a monohydric phenol compound (hereinafter this step may be described as “step 2”).

In other words, according to the present invention, a reaction between the dihydroxynaphthalene compound and benzyl alcohol is induced in the presence of an acid catalyst in the step 1 first; as a result, a benzyl-modified naphthalene compound (A) that has a structure in which a naphthylene structure serves as a main skeleton, each terminal of the main skeleton has a phenolic hydroxy group, and a benzyl group is pendant from the aromatic nucleus of the naphthylene structure, can be obtained. It should be noted that, in general, when a dihydroxynaphthalene compound is naphthylene-etherified in the presence of an acid catalyst, it is extremely difficult to adjust the molecular weight and the resulting product, has a high molecular weight. However, in the present invention, use of benzyl alcohol in combination suppresses the increase in molecular weight, and a resin suitable for electronic material usage can be obtained.

In the present invention, the benzyl group content in the target benzyl-modified naphthalene compound (A) can be adjusted by adjusting the amount of benzyl alcohol used; in addition, the melt viscosity of the benzyl-modified naphthalene compound (A) itself can be adjusted by this. In other words, the reaction ratio of the dihydroxynaphthalene compound to benzyl alcohol on a molar basis can be selected from the range in which the (dihydroxynaphthalene compound/benzyl alcohol) reaction ratio of the dihydroxynaphthalene compound to the benzyl alcohol is 1/0.1 to 1/10. However, from the viewpoint of the balance between heat resistance, flame retardancy, dielectric properties, and thermal decomposition resistance, the (dihydroxynaphthalene compound/benzyl alcohol) reaction ratio of the dihydroxynaphthalene compound to the benzyl alcohol is preferably within the range of 1/0.5 to 1/4.0.

Examples of the dihydroxynaphthalene compound that can be used include 1,2-dihydroxynaphthalene, 1,3-dihydroxynaphthalene, 1,4-dihydroxynaphthalene, 1,5-dihydroxynaphthalene, 1,6-dihydroxynaphthalene, 1,7-dihydroxynaphthalene, 1,8-dihydroxynaphthalene, 2,3-dihydroxynaphthalene, 2,6-dihydroxynaphthalene, and 2,7-dihydroxynaphthalene. Among these, 1,6-dihydroxynaphthalene and 2,7-dihydroxynaphthalene are preferable and 2,7-dihydroxynaphthalene is more preferable from the viewpoint of further improving the flame retardancy of the cured product of the obtained benzyl-modified naphthalene compound (A) and from the viewpoints of decreasing the loss tangent and improving the dielectric properties.

Examples of the acid catalyst that can be used in the reaction between the dihydroxynaphthalene compound and benzyl alcohol in the step 1 include inorganic acids such as phosphoric acid, sulfuric acid, and hydrochloric acid, organic acids such as oxalic acid, benzenesulfonic acid, toluenesulfonic acid, methanesulfonic acid, and fluoromethanesulfonic acid, and Friedel-Crafts reaction catalysts such as aluminum chloride, zinc chloride, stannic chloride, ferric chloride, and diethyl sulfate.

The amount of the acid catalyst used can be appropriately selected according to the target modification ratio or the like. For example, when an inorganic acid or an organic acid is used, the amount of the acid catalyst used relative to 100 parts by mass of the dihydroxynaphthalene compound is in the range of 0.001 to 5.0 parts by mass and preferably 0.01 to 3.0 parts by mass. When a Friedel-Crafts reaction catalyst is used, the amount relative to 1 mole of the dihydroxynaphthalene compound is in the range of 0.2 to 3.0 mol and preferably in the range of 0.5 to 2.0 mol.

The reaction between the dihydroxynaphthalene compound and benzyl alcohol in the step 1 can be performed without a solvent or can be performed with a solvent to increase the homogeneity of the reaction system. Examples of the solvent include mono- or diethers of ethylene glycol and diethylene glycol such as ethylene glycol dimethyl ether, ethylene glycol diethyl ether, ethylene glycol dipropyl ether, diethylene glycol dimethyl ether, diethylene glycol diethyl ether, diethylene glycol dipropyl ether, ethylene glycol monomethyl ether, ethylene glycol monoethyl ether, ethylene glycol monopropyl ether, diethylene glycol monomethyl ether, diethylene glycol monoethyl ether, diethylene glycol monopropyl ether, and diethylene glycol monobutyl ether; nonpolar aromatic solvents such as benzene, toluene, and xylene; aprotic polar solvents such as dimethylformamide and dimethyl sulfoxide; and chlorobenzene.

A specific method for performing the reaction in the step 1 may involve dissolving the dihydroxynaphthalene compound, the benzyl alcohol, and the acid catalyst in the absence or presence of the solvent, and conducting the reaction under a temperature condition of 60° C. to 180° C. and preferably about 80° C. to 160° C. The reaction time is not particularly limited but is preferably 1 to 10 hours. Specifically, this reaction can be performed by holding this temperature for 1 to 10 hours. Wafer generated during the reaction is preferably distilled away with a distilling column or the like since the reaction proceeds faster and the production efficiency is improved.

When the benzyl-modified naphthalene compound is extensively colored, an antioxidant or a reducing agent may be added to the reaction system to avoid coloring. Examples of the antioxidant include hindered phenol compounds such as 2,6-dialkylphenol derivatives, divalent sulfur compounds, and trivalent phosphorus-containing phosphite compounds. Examples of the reducing agent include hypophosphorous acid, phosphorous acid, thiosulfuric acid, sulfurous acid, hydrosulfite, and salts thereof.

After completion of the reaction, the acid catalyst is removed by a neutralization treatment, a wafer washing treatment, or decomposition. Then a common operation such as extraction or distillation is performed to isolate the desired phenolic-hydroxyl-containing resin. The neutralization treatment and the water washing treatment may be performed according to a common procedure. Examples of the neutralizing agent include basic, substances such as sodium hydroxide, potassium hydroxide, sodium carbonate, ammonia, triethylenetetramine, and aniline.

Examples of the aromatic dicarboxylic acid chloride include acid chlorides of phthalic acid, isophthalic acid, terephthalic acid, 2,6-naphthalenedicarboxylic acid, 1,6-naphthalenedicarboxylic acid, and 2,7-naphthalenedicarboxylic acid. Among these, isophthalic acid chloride and terephthalic acid chloride are preferred from the viewpoint of the balance between the solvent solubility and heat resistance.

Examples of the monohydric phenol compounds include phenol, cresol, p-t-butylphenol, 1-naphthol, and 2-naphthol. Among these, phenol, cresol, and 1-naphtol are preferable for their reactivity with carboxylic acid chloride. From the viewpoint of thermal decomposition resistance, 1-naphtol is more preferable.

A method for inducing a reaction between the benzyl-modified naphthalene compound (A), the aromatic dicarboxylic acid chloride, and the monohydric phenol compound can include, for example, inducing the reaction between these components in the presence of an alkali catalyst.

Examples of the alkali catalyst that can be used include sodium hydroxide, potassium hydroxide, triethylamine, and pyridine. Among these, sodium hydroxide and potassium hydroxide are preferred since they can be used as an aqueous solution and the production efficiency is improved.

Specifically, the reaction can involve mixing the components described above in the presence of an organic solvent, and inducing the reaction while continuously or intermittently adding the alkali catalyst or an aqueous solution thereof dropwise. During this process, the concentration of the aqueous solution of the alkali catalyst is preferably in the range of 3.0% to 30% by mass. Examples of the organic solvent that can be used include toluene, dichloromethane, and chloroform.

Upon completion of the reaction, the reaction solution is separated by being left to stand when an aqueous solution of the alkali catalyst was used, the wafer layer is removed, and the remaining organic layer is washed until the water layer after washing is substantially neutral. As a result, the desired resin can be obtained.

The active ester resin according to the present invention obtained as such preferably has a softening point of 100° C. to 200° C. since solubility in the organic solvent is increased and the resin is more suitable for use in a varnish for forming a circuit board. Moreover, the balance between heat resistance, flame retardancy, dielectric properties, and thermal decomposition resistance is excellent.

### <Epoxy Resin>

The epoxy resin used in the present invention will now be described.

Examples of the epoxy resin include bisphenol A epoxy resins, bisphenol F epoxy resins, bisphenol E epoxy resins, bisphenol S epoxy resins, bisphenol sulfide epoxy resins, biphenyl epoxy resins, tetramethyl biphenyl epoxy resins, polyhydroxy naphthalene epoxy resins, phenol novolac epoxy resins, cresol novolac epoxy resins, bisphenol A novolac epoxy resins, triphenylmethane epoxy resins, tetraphenylethane epoxy resins, dicyclopentadiene-phenol-addition reaction-type epoxy resins, phenol aralkyl epoxy resins, biphenyl aralkyl epoxy resins, biphenyl novolac epoxy resins, naphthol novolac epoxy resins, naphthol aralkyl epoxy resins, naphthol-phenol co-condensed novolac epoxy resins, naphthol-cresol co-condensed novolac epoxy resins, biphenyl-modified phenol epoxy resins (polyhydric phenol epoxy resins in which a phenol skeleton and a biphenyl skeleton are bonded to each other with a bismethylene group), biphenyl-modified naphthol epoxy resins (polyhydric naphthol epoxy resins in which a naphthol skeleton and a biphenyl skeleton are bonded to each other with a bismethylene group), alkoxy-containing aromatic ring-modified novolac epoxy resins (a compound in which a glycidyl-containing aromatic ring and an alkoxy-containing aromatic ring are bonded to each other with formaldehyde), phenylene ether epoxy resins, naphthylene ether epoxy resins, aromatic hydrocarbon formaldehyde resin-modified phenolic resin epoxy resins, and xanthene epoxy resins. These may be used alone or in combination.

Among these, from the viewpoint of obtaining a cured product with excellent dielectric properties and heat resistance, phenol novolac epoxy resins, cresol novolac epoxy resins, bisphenol A novolac epoxy resins, polyhydroxynaphthalene epoxy resins, triphenylmethane epoxy resins, tetraphenylethane epoxy resins, biphenyl novolac epoxy resins, naphthol novolac epoxy resins, naphthol-phenol co-condensed novolac epoxy resins, naphthol-cresol co-condensed novolac: epoxy resins, phenylene ether epoxy resins, naphthylene ether epoxy resins, and xanthene epoxy resins are particularly preferable.

Of these, from the viewpoint of obtaining a cured product with excellent dielectric properties, dicyclopentadiene-phenol addition-reaction epoxy resins, naphthol novolac epoxy resins, phenol aralkyl epoxy resins, biphenyl aralkyl epoxy resins, naphthol aralkyl epoxy resins, naphthol-phenol co-condensed novolac epoxy resins, naphthol-cresol co-condensed novolac epoxy resins, biphenyl-modified phenol epoxy resins (polyhydric phenol epoxy resins in which a phenol skeleton and a biphenyl skeleton are bonded to each other with a bismethylene group), biphenyl-modified naphthol epoxy resins (polyhydric naphthol epoxy resins in which a naphthol skeleton and a biphenyl skeleton are bonded to each other with a bismethylene group), alkoxy-containing aromatic ring-modified novolac epoxy resins (compounds in which a glycidyl-containing aromatic ring and an alkoxy-containing aromatic ring are bonded to each other with formaldehyde), aromatic hydrocarbon formaldehyde resin-modified phenol resin epoxy resins, and naphthylene ether epoxy resins are preferable.

### <Regarding Thermosetting Resin Composition>

From the viewpoint of improving curability and various physical properties of the cured product, the amounts of the active ester resin and the epoxy resin contained in the thermosetting resin composition, according to the present invention are preferably such that, per equivalent of epoxy groups in the epoxy resin, there is 0.8 to 1.5 equivalents of carbonyloxy groups constituting the ester in the active ester resin. In particular, preferably there are 0.8 to 1.3 equivalents of the carbonyloxy groups since the dielectric properties and heat resistance of the cured product can be improved while maintaining the excellent flame retardancy.

### (Other Curing Agent)

The thermosetting resin composition according to the present invention may contain a curing agent for epoxy resins in addition to the active ester resin and the epoxy resin described above. Examples of the curing agent for epoxy resins that can be used here include amine compounds, amide compounds, acid anhydride compounds, and phenol compounds. Specifically, examples of the amine compounds include diaminodiphenylmethane, diethylenetriamine, triethylenetetramine, diaminodiphenylsulfone, isophoronediamine, imidazole, BF3-amine complexes, and guanidine derivatives. Examples of the amide compounds include dicyandiamide and polyamide resins synthesized from a dimer of linoleic acid and ethylene diamine. Examples of the acid anhydride compounds include phthalic anhydride, trimellitic anhydride, pyromellitic anhydride, maleic anhydride, tetrahydrophthalic anhydride, methyltetrahydrophthalic anhydride, methylnadic anhydride, hexahydrophthalic anhydride, and methylhexahydrophthalic anhydride. Examples of the phenol compounds include polyhydric phenol compounds such as phenol novolac resin, cresol novolac resin, aromatic hydrocarbon formaldehyde resin-modified phenol resin, dicyclopentadiene phenol-added resin, phenol aralkyl resin, naphthol aralkyl resin, trimethylol methane resin, tetraphenylol ethane resin, naphthol novolac resin, naphthol-phenol co-condensed novolac resin, naphthol-cresol co-condensed novolac resin, biphenyl-modified phenol resin (polyhydric phenol compound having phenol nuclei linked with a bismethylene group), biphenyl-modified naphthol resin (polyhydric naphthol compound in which phenol nuclei are linked with a bismethylene group), and aminotriazine-modified phenol resin (polyhydric phenol compound having phenol nuclei linked with melamine, benzoguanamine, or the like).

Among these, those that contain many aromatic skeletons inside the molecule are preferable from the viewpoint of the flame retarding effect. Specifically, phenol novolac resin, cresol novolac resin, aromatic hydrocarbon formaldehyde-modified phenol resin, phenol aralkyl resin, naphthol aralkyl resin, naphthol novolac resin, naphthol-phenol co-condensed novolac resin, naphthol-cresol co-condensed novolac resin, biphenyl-modified phenol resin, biphenyl-modified naphthol resin, and aminotriazine-modified phenol resin are preferable for their excellent flame retardancy.

When the curing agents for epoxy resins described above are used in combination, the amount used is preferably in the range of 10% to 50% by mass from the viewpoint of dielectric properties.

If needed, a cure accelerator can be used in combination with the thermosetting resin composition according to the present invention. Various compounds can be used as the cure accelerator. Examples thereof include phosphorus compounds, tertiary amines, imidazole, organic acid metal salts, Lewis acids, and amine complex salts. In particular, for buildup material usage and circuit board usage, dimethylaminopyridine and imidazole are preferable for their excellent heat resistance, dielectric properties, and solder resistance, for example. For semiconductor sealing material usage, triphenylphosphine is preferred among the phosphorus compounds and 1,8-diazabicyclo-[5.4.0]-undecene (DBU) is preferred among the tertiary amines due to their excellent curability, heat resistance, electrical properties, moisture resistance reliability, etc.

### (Other Thermosetting Resin)

The curable resin composition according to the present invention may contain other thermosetting resin in addition to the active ester resin and the epoxy resin described in detail above. Examples of this “other thermosetting resin” include cyanate ester resins, benzoxazine resins, maleimide compounds, active ester resins, vinyl benzyl compounds, acrylic compounds, and copolymers of styrene and maleic anhydride. When the “other thermosetting resin” is used in combination, the amount used is not particularly limited as long as the effects of the present invention are not inhibited. Preferably, the amount is within the range of 1 to 50 parts by mass relative to 100 parts by mass of the thermosetting resin composition.

Examples of the cyanate ester resin include bisphenol A cyanate ester resins, bisphenol F cyanate ester resins, bisphenol E cyanate ester resins, bisphenol S cyanate ester resins, bisphenol M cyanate ester resins, bisphenol P cyanate ester resins, bisphenol Z cyanate ester resins, bisphenol AP cyanate ester resins, bisphenol sulfide cyanate ester resins, phenylene ether cyanate ester resins, naphthylene ether cyanate ester resins, biphenyl cyanate ester resins, tetramethylbiphenyl cyanate ester resins, polyhydroxynaphthalene cyanate ester resins, phenol novolac cyanate ester resins, cresol novolac cyanate ester resins, triphenylmethane cyanate ester resins, tetraphenylethane cyanate ester resins, dicyclopentadiene-phenol-addition-reaction cyanate ester resins, phenol aralkyl cyanate ester resins, naphthol novolac cyanate ester resins, naphthol aralkyl cyanate ester resins, naphthol-phenol co-condensed novolac cyanate ester resins, naphthol-cresol co-condensed novolac cyanate ester resins, aromatic hydrocarbon formaldehyde resin-modified phenol resin cyanate ester resins, biphenyl-modified novolac cyanate ester resins, and anthracene cyanate ester resins. These can be used alone or in combination.

Among these cyanate ester resins, bisphenol A cyanate ester resins, bisphenol F cyanate ester resins, bisphenol E cyanate ester resins, polyhydroxynaphthalene cyanate ester resins, naphthylene ether cyanate ester resins, and novolac cyanate ester resin are preferable from the viewpoint of obtaining a cured product having particularly excellent heat resistance. From the viewpoint of obtaining a cured product having excellent dielectric properties, dicyclopentadiene-phenol addition-reaction cyanate ester resins are preferable.

The benzoxazine resin is not particularly limited. Examples thereof include a reaction product of bisphenol F, formalin, and aniline (F-a benzoxazine resin), a reaction product of diaminodiphenylmethane, formalin, and phenol (P-d benzoxazine resin), a reaction product of bisphenol A, formalin, and aniline, a reaction product of dihydroxydiphenyl ether, formalin, and aniline, a reaction product of diaminodiphenyl ether, formalin, and phenol, a reaction product of a dicyclopentadiene-phenol-added resin, formalin, and aniline, a reaction product of phenolphthalein, formalin, and aniline, and a reaction product of diphenyl sulfide, formalin, and aniline. These can be used alone or in combination.

Examples of the maleimide compounds include various compounds represented by any of structural formulae (i) to (iii) below:

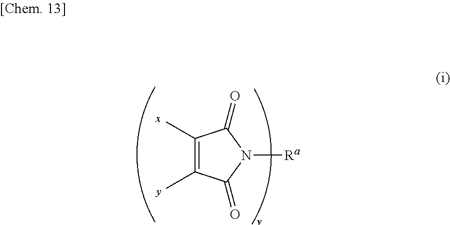

(In formula (i), R^{a} represents a v-valent organic group, x and y each independently represent a hydrogen atom, a halogen atom, an alkyl group, or an aryl group, and v represents an integer of 1 or more.)

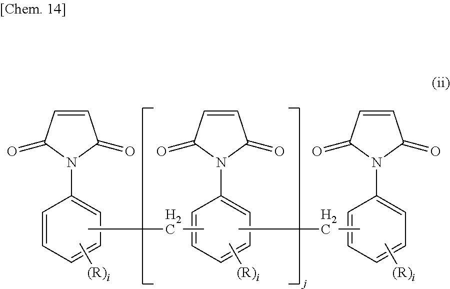

(In formula (ii), R represents a hydrogen atom, an alkyl group, an aryl group, an aralkyl group, a halogen atom, a hydroxyl group, or an alkoxy group, i represents an integer of 1 to 3, and j represents an average of the number of repeating units and is 0 to 10.)

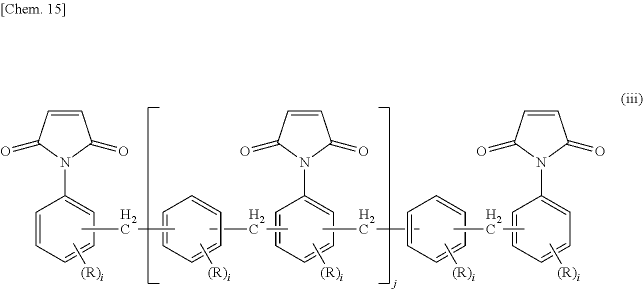

(In formula (iii), R represents a hydrogen atom, an alkyl group, an aryl group, an aralkyl group, a halogen atom, a hydroxyl group, or an alkoxy group, i represents an integer of 1 to 3, and 1 represents an average of the number of repeating units and is 0 to 10.) These can be used alone or in combination.

The active ester resin that serves as the “other thermosetting resin” is not particularly limited. In general, a compound having two or more highly reactive ester groups in the molecule is preferable for use. Examples thereof include phenol esters, thiophenol esters, N-hydroxyamine esters, and esters of heterocyclic hydroxy compounds. The active ester resin is preferably an active ester resin obtained by a condensation reaction between a carboxylic acid compound and/or a thiocarboxylic acid compound and a hydroxy compound and/or a thiol compound. In particular, from the viewpoint of improving heat resistance, an active ester resin obtained from a carboxylic acid compound or a halide thereof, and a hydroxy compound is preferable, and an active ester resin obtained from a carboxylic acid compound or a halide thereof, and a phenol compound and/or a naphthol compound is more preferable. Examples of the carboxylic acid compound include benzoic acid, acetic acid, succinic acid, maleic acid, itaconic acid, phthalic acid, isophthalic acid, terephthalic acid, pyromellitic acid, and halides of the foregoing. Examples of the phenol compound and the naphthol compound include hydroquinone, resorcinol, bisphenol A, bisphenol F, bisphenol S, dihydroxy diphenyl ether, phenol phthalein, methylated bisphenol A, methylated bisphenol F, methylated bisphenol S, phenol, o-cresol, m-cresol, p-cresol, catechol, α-naphthol, β-naphthol, 1,5-dihydroxynaphthalene, 1,6-dihydroxynaphthalene, 2,6-dihydroxynaphthalene, dihydroxybenzophenone, trihydroxybenzophenone, tetrahydroxybenzophenone, phloroglucin, benzene triol, and dicyclopentadiene-phenol-added resin.

Specifically, preferable examples of the active ester resin include an active ester resin that contains a dicyclopentadiene-phenol added structure, an active ester resin containing a naphthalene structure, an active ester resin which is an acetylated product of phenol novolac, and an active ester resin which is a benzoylated product of a phenol novolac. From the viewpoint of improving peal strength, an active ester resin that contains a dicyclopentadiene-phenol-added structure and an active ester resin that contains a naphthalene structure are more preferable. More specifically, examples of the active ester resin that contains a dicyclopentadiene-phenol added structure include compounds represented by general formula (iv) below:

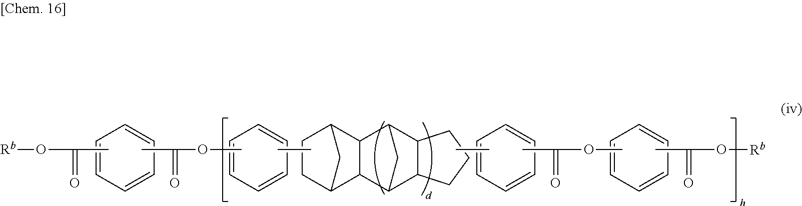

[In the formula, R^{b} represents a phenyl group or a naphthyl group, d represents 0 or 1, and h represents an average of the number of repeating units and is 0.05 to 2.5.]

From the viewpoints of decreasing the loss tangent of the cured product of the resin composition and improving the heat resistance, Rb preferably represents a naphthyl group, d preferably represents 0, and h is preferably 0.25 to 1.5.

The thermosetting resin composition according to the present invention described in detail above exhibits excellent solubility in a solvent. Thus, the thermosetting resin composition preferably contains an organic solvent in addition to the components described above. Examples of the organic solvent that can be used include methyl ethyl ketone, acetone, dimethylformamide, methyl isobutyl ketone, methoxypropanol, cyclohexanone, methylcellosolve, ethyl diglycol acetate, and propylene glycol monomethyl ether acetate. The choice and the appropriate amount of use may be appropriately selected according to the usage. For example, for a printed board usage, a polar solvent having a boiling point of 160° C. or lower, such as methyl ethyl ketone, acetone, or a 1-methoxy-2-propanol, is preferable, and the solvent is preferably used in such an amount that the nonvolatile content is 40% to 80% by mass. For buildup adhesive film usage, the organic solvent is preferably a ketone, such as acetone, methyl ethyl ketone, or cyclohexanone, an acetic acid ester such as ethyl acetate, butyl acetate, cellosolve acetate, propylene glycol monomethyl ether acetate, or carbitol acetate, a carbitol such as cellosolve or butyl carbitol, an aromatic hydrocarbon such as toluene or xylene, dimethyl formamide, dimethyl acetamide, or N-methyl pyrrolidone. The solvent is preferably used in such an amount that the nonvolatile content is 30% to 60% by mass.

In order for the thermosetting resin composition to exhibit flame retardancy, for example, in the field of printed boards, a non-halogen flame retardant substantially free of any halogen atom may be added as long as the reliability is not degraded.

Examples of the non-halogen flame retardant include phosphorus flame retardants, nitrogen flame retardants, silicone flame retardants, inorganic flame retardants, and organic metal salt flame retardants. The use of these flame retardants is not particularly limited. These can be used alone, two or more flame retardants of the same system can be used, or two or more flame retardants of different systems can be used.

The phosphorus flame retardants may be inorganic or organic. Examples of the inorganic compound include ammonium phosphates such as red phosphorus, monoammonium phosphate, diammonium phosphate, triammonium phosphate, and ammonium polyphosphate, and inorganic nitrogen-containing phosphorus compounds such as phosphoric acid amide.

The red phosphorus is preferably surface-treated to prevent hydrolysis or the like. Examples of the surface treatment method include (i) a method of coating the red phosphorus with an inorganic compound such as magnesium hydroxide, aluminum hydroxide, zinc hydroxide, titanium hydroxide, bismuth oxide, bismuth hydroxide, bismuth nitrate, or a mixture thereof; (ii) a method of coating the red phosphorus with a mixture of an inorganic compound, such as magnesium hydroxide, aluminum hydroxide, zinc hydroxide, or titanium hydroxide, and a thermosetting resin, such as a phenol resin; and (iii) a method of double-coating the red phosphorus with an inorganic compound such as magnesium hydroxide, aluminum hydroxide, zinc hydroxide, or titanium hydroxide, and a thermosetting resin, such as a phenol resin, on the coating of the inorganic compound.

Examples of the organophosphorus compounds include common organophosphorus compounds such as phosphate ester compounds, phosphonic acid compounds, phosphinic acid compounds, phosphine oxide compounds, phosphorane compounds, and organic nitrogen-containing phosphorus compounds; cyclic organophosphorus compounds such as 9,10-dihydro-9-oxa-10-phosphaphenanthrene=10-oxide, 10-(2,5-dihydrooxyphenyl)-10H-9-oxa-10-phosphaphenanthrene=10-oxide, and 10-(2,7-dihydrooxynaphthyl)-10H-9-oxa-10-phosphaphenanthrene=10-oxide; and derivatives obtained by inducing a reaction between a cyclic organophosphorus compound and a compound such as epoxy resin or a phenol resin.

The amount used is appropriately selected based on the type of the phosphorus flame retardant, other components of the thermosetting resin composition, and the desired level of flame retardancy. For example, in 100 parts by mass of a thermosetting resin composition that contains an active ester resin, an epoxy resin, a non-halogen flame retardant, and other fillers and additives, the amount of the red phosphorus used as the non-halogen flame retardant is preferably in the range of 0.1 to 2.0 parts by mass. If an organophosphorous compound is used, the amount thereof is preferably in the range of 0.1 to 10.0 parts by mass and is more preferably in the range of 0.5 to 6.0 parts by mass.

When the phosphorus flame retardant is used, it can be used in combination with hydrotalcite, magnesium hydroxide, boron compound, zirconium oxide, a black dye, calcium carbonate, zeolite, zinc molybdate, activated charcoal, or the like.

Preferable examples of the nitrogen flame retardant include triazine compounds, cyanuric acid compounds, isocyanuric acid compounds, and phenothiazine. The triazine compounds, cyanuric acid compounds, and isocyanuric acid compounds are preferable.

Examples of the triazine compounds include melamine, acetoguanamine, benzoguanamine, melon, melam, succinoguanamine, ethylene dimelamine, melamine polyphosphate, and triguanamine. Other examples include aminotriazine sulfate compounds such as guanyl melamine sulfate, melem sulfate, and melamine sulfate, aminotriazine-modified phenol resins, and the aminotriazine-modified phenol resins further modified by tung oil, isomerized linseed oil, or the like.

Specific examples of the cyanuric acid compounds include cyanuric acid and melamine cyanurate.

The amount of the nitrogen flame retardant contained is appropriately selected based on the type of the nitrogen flame retardant, other components of the thermosetting resin composition, and the desired level of flame retardancy. For example, in 100 parts by mass of a thermosetting resin composition that contains an active ester resin, an epoxy resin, a non-halogen flame retardant, and other fillers and additives, the amount of the nitrogen flame retardant is preferably in the range of 0.05 to 10 parts by mass and is more preferably in the range of 0.1 to 5 parts by mass.

The nitrogen flame retardant may be used in combination with a metal hydroxide, a molybdenum compound, or the like.

The silicone flame retardant may be any organic compound that contains silicon atoms. Examples thereof include silicone oil, silicone rubber, and silicone resin.

The amount of the silicone flame retardant used is appropriately selected based on the type of the silicone flame retardant, other components of the thermosetting resin composition, and the desired level of flame retardancy. For example, in 100 parts by mass of a thermosetting resin composition that contains an active ester resin, an epoxy resin, a non-halogen flame retardant, and other fillers and additives, the amount of the silicone flame retardant is preferably in the range of 0.05 to 20 parts by mass. The silicone flame retardant may be used in combination with a molybdenum compound, alumina, or the like.

Examples of the inorganic flame retardant include metal hydroxides, metal oxides, metal carbonate compounds, metal powder, boron compounds, and low-melting-point glass.

Specific examples of the metal hydroxides include aluminum hydroxide, magnesium hydroxide, dolomite, hydrotalcite, calcium hydroxide, barium hydroxide, and zirconium hydroxide.

Specific examples of the metal oxides include zinc molybdate, molybdenum trioxide, zinc stannate, tin oxide, aluminum oxide, iron oxide, titanium oxide, manganese oxide, zirconium oxide, zinc oxide, molybdenum oxide, cobalt oxide, bismuth oxide, chromium oxide, nickel oxide, copper oxide, and tungsten oxide.

Specific examples of the metal carbonate compounds include zinc carbonate, magnesium carbonate, calcium carbonate, barium carbonate, basic magnesium carbonate, aluminum carbonate, iron carbonate, cobalt carbonate, and titanium carbonate.

Specific examples of the metal powder include powder of aluminum, iron, titanium, manganese, zinc, molybdenum, cobalt, bismuth, chromium, nickel, copper, tungsten, and tin.

Specific examples of the boron compounds include zinc borate, zinc metaborate, barium metaborate, boric acid, and borax.

Specific examples of the low-melting-point glass include Sheeplee (Bokusui Brown Co., Ltd.), hydrated glass SiO₂—MgO—H₂O, and glassy compounds based on PbO—B₂O₃, ZnO—P₂O₅—MgO, P₂O₅—B₂O₃—PbO—MgO, P—Sn—O—F, PbO—V₂O₅—TeO₂, Al₂O₃—H₂O, and lead borosilicate.

The amount of the inorganic flame retardant used is appropriately selected based on the type of the inorganic flame retardant, other components of the thermosetting resin composition, and the desired level of flame retardancy. For example, in 100 parts by mass of a thermosetting resin composition that contains an active ester resin, an epoxy resin, a non-halogen flame retardant, and other fillers and additives, the amount of the inorganic flame retardant contained is preferably in the range of 0.05 to 20 parts by mass and in particular in the range of 0.5 to 15 parts by mass.

Examples of the organic metal salt flame retardant include ferrocene, an acetylacetonate metal complex, an organometallic carbonyl compound, an organic cobalt salt compound, an organic sulfonic acid metal salt, and a compound in which a metal atom is bonded to an aromatic compound or a heterocyclic compound with an ionic bond or a coordinate bond.

The amount of the organic metal salt flame retardant used is appropriately selected based on the type of the organic metal salt flame retardant, other components of the thermosetting resin composition, and the desired level of flame retardancy. For example, in 100 parts by mass of a thermosetting resin composition that contains an active ester resin, an epoxy resin, a non-halogen flame retardant, and other fillers and additives, the amount of the organic metal salt flame retardant is preferably in the range of 0.005 to 10 parts by mass.

The thermosetting resin composition according to the present invention may contain an inorganic filler, if needed. Examples of the inorganic filler include fused silica, crystalline silica, alumina, silicon nitride, and aluminum hydroxide. When the amount or the inorganic filler added is particularly large, fused silica is preferably used. Fused silica may be angular or spherical; however, in order to suppress the increase in melt viscosity of a molding material and to increase the amount of the fused silica used, spherical silica is preferably mainly used. In order to increase the amount of the spherical silica used, the particle size distribution of the spherical silica is preferably optimized. The fill ratio is preferably high in view of flame retardancy and is particularly preferably 20% by mass or more relative to the total amount of the thermosetting resin composition. For conductive paste usage or the like, an electrically conductive filler, such as silver powder or copper powder, can be used.

The thermosetting resin composition according to the present invention may contain various additives such as a silane coupling agent, a mold releasing agent, a pigment, and an emulsifier, if needed.

The thermosetting resin composition according to the present invention is obtained by homogeneously mixing the components described above. The thermosetting resin composition according to the present invention, which contains an active ester resin according to the present, invention, an epoxy resin, and, if needed, a cure accelerator can be easily formed into a cured product, through the same method as those known in the art. Examples of the cured product, include formed and cured products such as a laminate, a cast, product, an adhesive layer, a coating film, and a film.

Examples of the usage of the thermosetting resin composition according to the present invention include hard printed wiring board material, resin compositions for flexible wiring boards, insulating materials for circuit boards such as interlayer insulating materials for buildup substrates, semiconductor sealing materials, conductive paste, adhesive films for buildup, resin casting materials, and adhesives. For use in hard printed wiring board materials, insulating materials for electronic circuit boards, and adhesive films for buildup among the usages described above, the composition can be used as an insulating material for a substrate with built-in electronic parts, in which passive elements such as capacitors and active elements such as IC chips are embedded in the substrate. Because of the properties such as high flame retardancy, high heat resistance, low thermal expansion, and solvent solubility, the composition is preferably used in the hard printed wiring board material, the resin composition for flexible wiring boards, materials for circuit boards such as interlayer insulating materials for buildup substrates, and the semiconductor sealing material among these usages.

Here, the circuit board according to the present invention is produced by diluting a thermosetting resin composition in an organic solvent to obtain a varnish, shaping the varnish into a plate, stacking the plate and a copper foil, and pressure-forming the resulting stack under heating. Specifically, for example, in order to produce a hard printed wiring board, a varnish-like thermosetting resin composition containing the organic solvent is further mixed with an organic solvent to prepare a varnish, a reinforcing substrate is impregnated with the varnish, the varnish is semi-cured to obtain a prepreg according to the present invention, and a copper foil is stacked on the prepreg, followed by pressure-bonding under heating. Examples of the reinforcing substrate that can be used here include paper, glass cloth, glass nonwoven cloth, aramid paper, aramid cloth, glass mat, and glass roving cloth. This method is further described in detail. That is, first, a varnish-like thermosetting resin composition is heated to a heating temperature suitable for the type of the solvent used, preferably 50° C. to 170° C., to obtain a prepreg, which is a cured product. During this process, the mass ratio of the thermosetting resin composition and the reinforcing substrate used is not particularly limited. Usually, the ratio is preferably adjusted so that the resin content in the prepreg is 20% to 60% by mass. Next, the prepreg obtained as described above is stacked by a common method, a copper foil is stacked thereon, and the resulting stack is pressure-bonded at a pressure of 1 to 10 MPa under heating at 170° C. to 250° C. for 10 minutes to 3 hours. As a result, the desired circuit board can be obtained.

In order to produce a flexible wiring board from the thermosetting resin composition according to the present invention, an active ester resin, an epoxy resin, and an organic solvent are mixed, and the resulting mixture is applied to an electrically insulating film with a coater such as a reverse roll coater, a comma coater, or the like. Then the applied mixture is heated with a heater to 60° C. to 170° C. for 1 to 15 minutes to evaporate the solvent and to obtain a B-stage adhesive composition. Next, a heating roil or the like is used to thermally press-bond a metal foil onto the adhesive. The press-bonding pressure during this step is preferably 2 to 200 N/cm and the press-bonding temperature is preferably 40° C. to 200° C. If sufficient bonding performance is obtained by this, the process may end here. However, when complete cure is needed, post-curing is preferably performed at 100° C. to 200° C. for 1 to 24 hours. The thickness of the adhesive composition film after the final curing is preferably in the range of 5 to 100 μm.

An example of the method for obtaining an interlayer insulating material for a buildup substrate from the thermosetting resin composition according to the present invention is a method that includes applying the thermosetting resin composition, which is blended with rubber, a filler, and other appropriate components, to a wiring board having a circuit by a spray coating technique, a curtain coating technique, or the like, and curing the applied composition. Then if needed, holes such as through holes are formed at predetermined positions, a treatment with a roughening agent is performed, and the surface is washed with warm water to form irregularities. Then a metal such as copper is plated. The plating method is preferably electroless plating or electroplating. Examples of the roughening agent include an oxidant, an alkali, and an organic solvent. These operations are repeated as needed to alternately build up resin insulating layers and conductor layers with predetermined circuit patterns, and a buildup substrate is obtained as a result. Formation of holes such as through holes are performed after forming of the outermost resin insulating layers. Alternatively, a resin-clad copper foil prepared by semi-curing the resin composition on the copper foil can be press-bonded onto a wiring board having a circuit under heating at 170° C. to 250° C. so as to form a buildup substrate without having to perform the steps of surface roughening and plating.

Next, an example of a method for producing a semiconductor sealing material from the thermosetting resin composition according to the present invention includes thoroughly melting and mixing an active ester resin, an epoxy resin, and additives such as an inorganic filler in an extruder, a kneader, a roll, or the like as needed until a homogeneous mixture is obtained. During this process, silica is usually used as the inorganic filler; and the inorganic filler is added such that the ratio thereof is 70% to 95% by mass in the thermosetting resin composition. As a result, a semiconductor sealing material according to the present invention is obtained. An example of a method for forming a semiconductor package includes casting the composition or shaping the composition by using a transfer molding machine or injection molding machine, and heating the formed composition at 50° C. to 200° C. for 2 to 10 hours. The formed product obtained as such is a semiconductor device.

An example of a method for producing an adhesive film for buildup from the thermosetting resin composition according to the present invention includes applying the thermosetting resin composition according to the present invention to a supporting film so as to form a resin composition layer. As a result, an adhesive film for a multilayer printed wiring board is obtained.

When the thermosetting resin composition according to the present invention is used as an adhesive film for buildup, it is important that the adhesive film soften under temperature conditions (usually 70° C. to 140° C.) of lamination by a vacuum lamination method and that the adhesive film exhibit flowability (resin flow) that enables the resin to fill the via holes or through holes present in the circuit-board during the lamination of the circuit board. The components described above are preferably blended such that these properties are exhibited.

The diameter of the through holes in the multilayer printed wiring board is usually 0.1 to 0.5 mm and the depth is usually 0.1 to 1.2 mm. It is preferable to cause holes within these ranges to be filled with the resin. When both sides of the circuit board are laminated, the through holes are preferably about half-filled with the resin.

Specifically, the adhesive film can be produced by preparing a varnish-like thermosetting resin composition according to the present invention, applying the varnish-like composition to a surface of a supporting film, and drying the organic solvent by heating or with hot air so as to form a layer (α) of the thermosetting resin composition.

The thickness of the layer (α) to be formed is usually to be equal to or larger than the thickness of the conductor layer. Since the thickness of a conductor layer of a circuit board is usually in the range of 5 to 70 μm, the thickness of the resin composition layer is preferably 10 to 100 μm.

The layer (α) may be protected with a protective film described below. When the layer is protected with a protective film, adhesion of foreign matter onto a surface of the resin composition layer and scratching can be prevented.

Examples of the supporting film and the protective film include polyolefins such as polyethylene, polypropylene, and polyvinyl chloride, polyesters such as polyethylene terephthalate (hereinafter may be referred, to as “PET”) and polyethylene naphthalate, polycarbonate, polyimide, releasing paper, and metal foils such as copper and aluminum foils. The supporting film and the protective film may be subjected to a MAD treatment, a corona treatment, or a releasing treatment.

The thickness of the supporting film is not particularly limited but is usually 10 to 150 μm and is preferably in the range of 25 to 50 μm. The thickness of the protective film is preferably 1 to 40 μm.

The supporting film is removed after the supporting film is laminated to the circuit board or after formation of an insulating layer by thermal curing. When the supporting film is removed after the adhesive film is thermally cured, adhesion of foreign matter during the curing step can be prevented. When removal is to be conducted after curing, the supporting film is usually preliminarily subjected to a releasing treatment.

A method for producing a multilayer printed wiring board by using the adhesive film obtained as described above includes, for example, removing the protective film if the layer (α) is protected with the protective film, and laminating the layer (α) onto one or both sides of the circuit board by, for example, a vacuum lamination method so that the layer (α) is in direct contact with the circuit board. The lamination method may be batch lamination or continuous lamination using rolls. Prior to lamination, the adhesive film and the circuit board may be heated (preheated) as needed.

Preferable conditions for lamination are a press-bonding temperature (lamination temperature) of 70° C. to 140° C. and a press-bonding pressure of 1 to 11 kgf/cm² (9.8×10⁴ to 107.9×10⁴ N/m²), and lamination is preferably conducted at a reduced pressure, for example, an air pressure of 20 mmHg (26.7 hPa) or less.

Examples of the method of using the thermosetting resin composition according to the present invention as conductive paste include a method of dispersing fine conductive particles in the thermosetting resin composition to prepare a composition for an anisotropic conductive film and a method for preparing a paste resin composition for circuit connection or an anisotropic conductive adhesive, which is liquid at room temperature, from the thermosetting resin composition.

The thermosetting resin composition according to the present invention can also be used as a resist ink. In such a case, a vinyl monomer having an ethylenic unsaturated double bond and a cation polymerization catalyst serving as a curing agent are added to the thermosetting resin composition, and a pigment, talc, and a filler are added to the resulting mixture to prepare a composition for a resist ink. Then the composition is applied to a printed board by a screen printing technique, and then formed into a resist ink cured product.

A method for obtaining a cured product according to the present invention may include heating the composition, which is obtained through the method described above, within the temperature range of about 20° C. to 250° C.

Thus, according to the present invention, a thermosetting resin composition that exhibits excellent environmental properties and a high level of flame retardancy without using a halogen flame retardant can be obtained. A cured product prepared therefrom exhibits excellent dielectric properties and can increase the operation speed of high-frequency devices. An active ester resin according to the present invention can be easily and efficiently produced by the production method according to the present invention, and a molecular design that meets the desired level of performance can be realized.

### EXAMPLES

Next, the present invention is specifically described through Examples and Comparative Examples. In the description below, “parts” and “%” are on a mass basis unless otherwise noted. The softening point measurement, GPC measurement, and GC-TOF-MS spectrum and MALBI-TOF-MS spectrum measurement were conducted under the following conditions.
1) Softening point measurement method: Conducted according to JIS K 7234
2) GPC measurement
Instrument: By using “HLC-8220 GPC” produced by TOSOH CORPORATION, measurement was conducted under the following conditions:
Columns: guard column “HXL-L” produced by TOSOH CORPORATION,
   “TSK-GEL G2000HXL” produced by TOSOH CORPORATION
   “TSK-GEL G2000HXL” produced by TOSOH CORPORATION
   “TSK-GEL G3000HXL” produced by TOSOH CORPORATION
   “TSK-GEL G4000HXL” produced by TOSOH CORPORATION
Column temperature: 40° C.
Solvent: tetrahydrofuran
Flow rate: 1 ml/min
Detector: RI
3) GC-TOF-MS spectrum
Instrument: JMS-T100GC, produced by JEOL Ltd.
Ionization method: field desorption ionization method
4) MALDI-TOF-MS spectrum
Instrument: AXIMA-TOF2, produced by Shimadzu/KRSTOS
Ionization method: matrix-assisted laser desorption ionization

### Synthetic Example 1

Into a flask equipped with a thermometer, a dropping funnel, a condenser, a distilling column, and a stirrer, 320 g (2.0 mol) of 2,7-dihydroxynaphthalene, 184 g (1.7 mol) of benzyl alcohol, and 5.0 g of p-toluenesulfonic acid monohydrate were charged. The mixture was stirred at room temperature while blowing nitrogen. The mixture was then heated to 150° C. and stirred for 4 hours while removing the produced water to outside the system. Upon completion of the reaction, 900 g of methyl isobutyl ketone and 5.4 g of a 20% aqueous solution of sodium hydroxide were added to neutralize the mixture, the water layer was removed by separation, and the residue was washed with 280 g of water three times. Methyl isobutyl ketone was removed at a reduced pressure to obtain 460 g of a benzyl-modified naphthalene compound (A-1). The benzyl-modified naphthalene compound (A-1) was black solid, and the hydroxyl equivalent was 180 g/eq.

### Synthetic Example 2

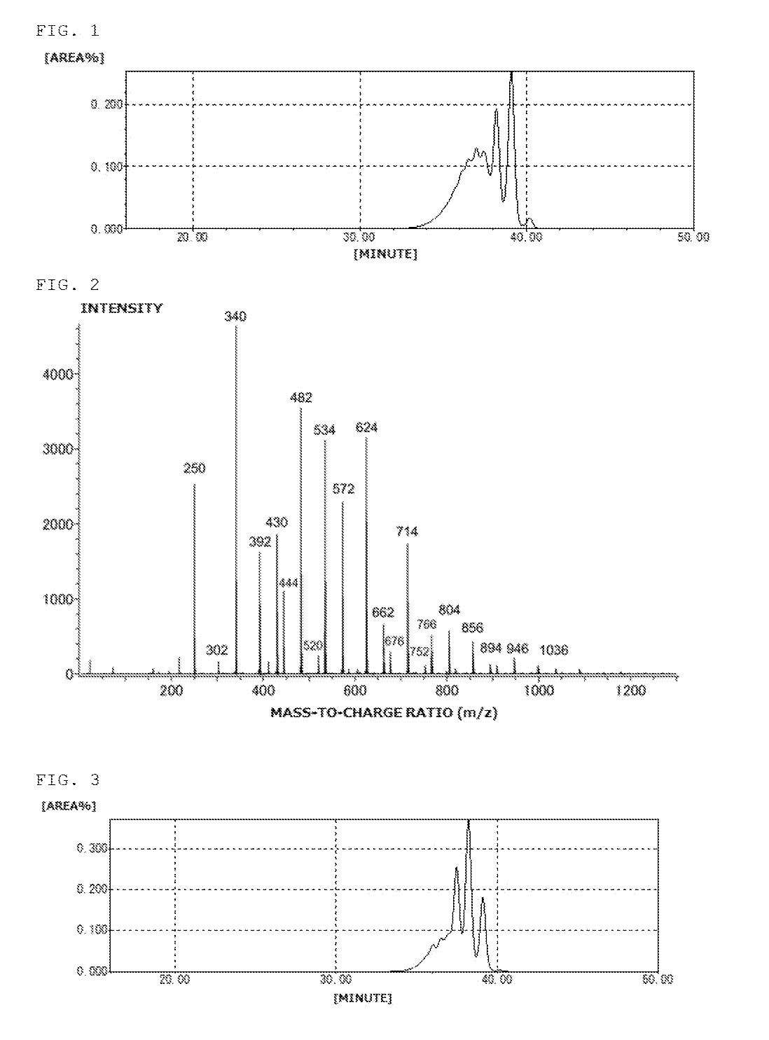

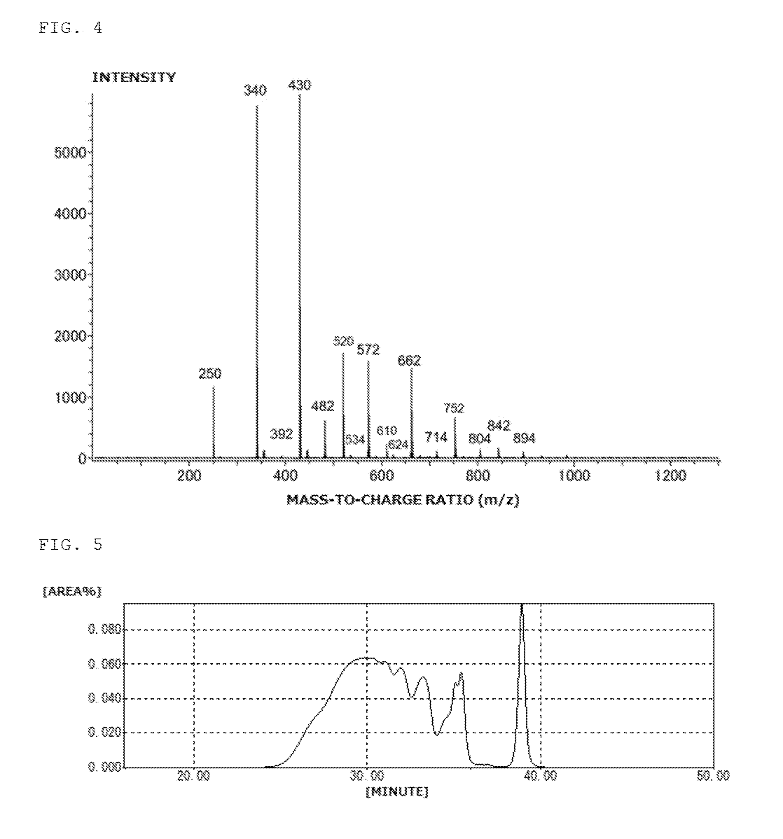

Into a flask equipped with a thermometer, a dropping funnel, a condenser, a distilling column, and a stirrer, 160g (1.0 mol) of 2,7-dihydroxynaphthalene, 108 g (1.0 mol) of benzyl alcohol, and 2.7 g of p-toluenesulfonic acid monohydrate were charged. The mixture was stirred at room temperature while blowing nitrogen. The mixture was then heated to 150° C. and stirred for 4 hours while removing the produced water to outside the system. Upon completion of the reaction, 500 g of methyl isobutyl ketone and 2.8 g of a 20% aqueous solution of sodium hydroxide were added to neutralize the mixture, the water layer was removed by separation, and the residue was washed with 150 g of water three times. Methyl isobutyl ketone was removed at a reduced pressure to obtain 250 g of a benzyl-modified naphthalene compound (A-2). The benzyl-modified naphthalene compound (A-2) was black solid, and the hydroxyl equivalent was 180 g/eq. The GPC chart of the benzyl-modified naphthalene compound (A-2) is shown in FIG. 1 and its GC-TOF-MS spectrum is shown in FIG. 2.

In the GC-TOF-MS spectrum results, a peak indicating the sum (M+=250) of the molecular weight of 2,7-dihydroxynaphthalene (Mw: 160) and the molecular weight of one benzyl group (Mw: 90), a peak indicating the sum (M+=340) of the molecular weights of 2,7-dihydroxynaphthalene and two benzyl groups, a peak indicating the sum (M+=430) of the molecular weights of 2,7-dihydroxynaphthalene and three benzyl groups, and a peak indicating the sum (M+=520) of the molecular weights of 2,7-dihydroxynaphthalene and four benzyl groups were confirmed. Furthermore, a peak indicating the sum (M+=392) of the molecular weight of a 2,7-dihydroxynaphthalene dimer structure (Mw: 302) produced by bimolecular dehydration and the molecular weight of one benzyl group (Mw: 90), a peak indicating the sum (M+=482) of the molecular weights of the dimer structure and two benzyl groups, a peak indicating the sum (M+=572) of the molecular weights of the dimer structure and three benzyl groups, a peak indicating the sum (M+=662) of the molecular weights of the dimer structure and four benzyl groups, and a peak indicating the sum (M+=752) of the molecular weights of the dimer structure and five benzyl groups were confirmed. Furthermore, a peak indicating the sum (M+=534) of the molecular weight of a 2,7-dihydroxynaphthalene trimer structure (Mw: 444) produced by trimolecular dehydration and the molecular weight of one benzyl group (Mw: 90), a peak indicating the sum (M+=624) of the molecular weights of the trimer structure and two benzyl groups, a peak indicating the sum (M+=714) of the molecular weights of the trimer structure and three benzyl groups, a peak indicating the sum (M+=804) of the molecular weights of the trimer structure and four benzyl groups, and a peak indicating the sum (M+=894) of the molecular weights of the trimer structure and five benzyl groups were confirmed. Also, a peak indicating the sum (M+=676) of the molecular weight of a 2,7-dihydroxynaphthalene tetramer structure (Mw: 586) produced by tetramolecular dehydration and the molecular weight of one benzyl group (Mw: 90), a peak indicating the sum (M+=766) of the molecular weights of the tetramer structure and two benzyl groups, a peak indicating the sum (M+=856) of the molecular weights of the tetramer structure and three benzyl groups, a peak indicating the sum (M+=946) of the molecular weights of the tetramer structure and four benzyl groups, and a peak indicating the sum (M+=1036) of the molecular weights of the tetramer structure and five benzyl groups were confirmed.

### Synthetic Example 3

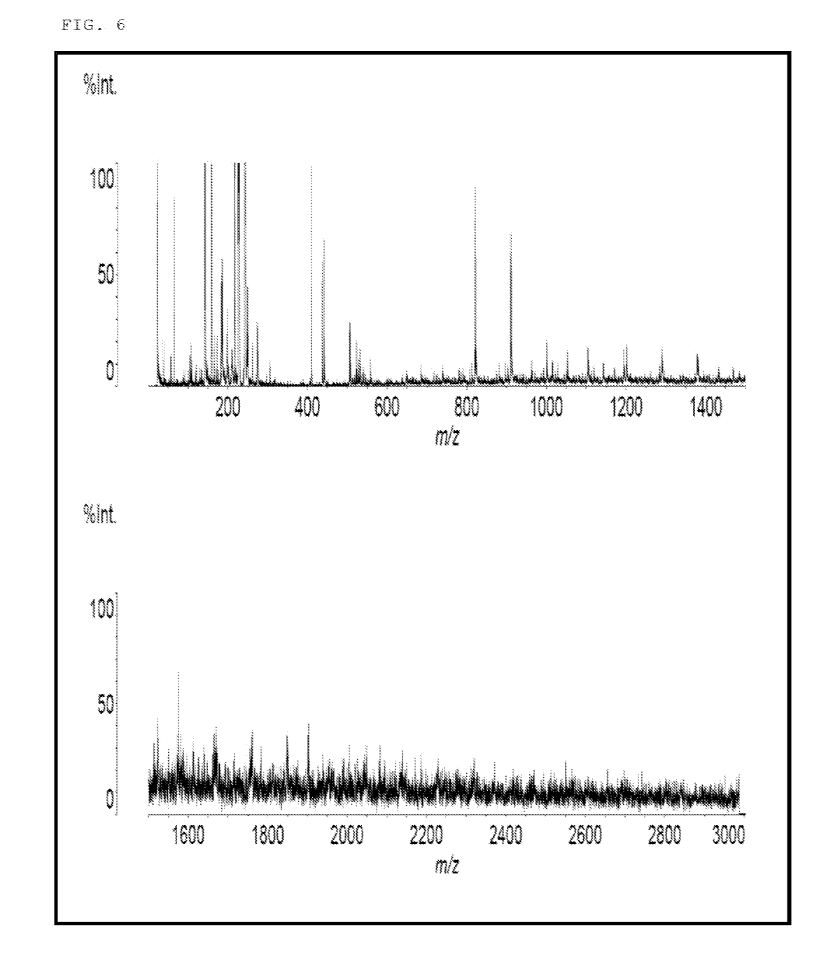

Into a flask equipped with a thermometer, a dropping funnel, a condenser, a distilling column, and a stirrer, 160 g (1.0 mol) of 2,7-dihydroxynaphthalene, 216 g (2.0 mol) of benzyl alcohol, and 3.8 g of p-toluenesulfonic: acid monohydrate were charged. The mixture was stirred at room temperature while blowing nitrogen. The mixture was then heated to 150° C. and stirred for 4 hours while removing the produced wafer to outside the system. Upon completion of the reaction, 680 g of methyl isobutyl ketone and 4.0 g of a 20% aqueous solution of sodium hydroxide were added to neutralize the mixture, the water layer was removed by separation, and the residue was washed with 170 g of water three times. Methyl isobutyl ketone was removed at a reduced pressure to obtain 330 g of a benzyl-modified naphthalene compound (A-3). The benzyl-modified naphthalene compound (A-3) was black solid, and the hydroxyl equivalent was 200 g/eq. The GPC chart of the benzyl-modified naphthalene compound (A-3) is shown in FIG. 3 and its GC-TOF-MS spectrum is shown in FIG. 4.

In the GC-TOF-MS spectrum results, a peak indicating the sum (M+=250) of the molecular weight of 2,7-dihydroxynaphthalene (Mw: 160) and the molecular weight of one benzyl group (Mw: 90), a peak indicating the sum (M+=340) of the molecular weights of 2,7-dihydroxynaphthalene and two benzyl groups, a peak indicating the sum (M+=430) of the molecular weights of 2,7-dihydroxynaphthalene and three benzyl groups, a peak indicating the sum (M+=520) of the molecular weights of 2,7-dihydroxynaphthalene and four benzyl groups, and a peak indicating the sum (M+=610) of the molecular weights of 2,7-dihydroxynaphthalene and five benzyl groups were confirmed. Furthermore, a peak indicating the sum (M+=392) of the molecular weight of a 2,7-dihydroxynaphthalene dimer structure (Mw: 302) produced by bimolecular dehydration and the molecular weight of one benzyl group (Mw: 90), a peak indicating the sum (M+=482) of the molecular weights of the dimer structure and two benzyl groups, a peak indicating the sum (M+=572) of the molecular weights of the dimer structure and three benzyl groups, a peak indicating the sum (M+=662) of the molecular weights of the dimer structure and four benzyl groups, a peak indicating the sum (M+=752) of the molecular weights of the dimer structure and five benzyl groups, and a peak indicating the sum (M+=842) of the molecular weights of the dimer structure and six benzyl groups were confirmed. Furthermore, a peak indicating the sum (M+=534) of the molecular weight of a 2,7-dihydroxynaphthalene trimer structure (Mw: 444) produced by trimolecular dehydration and the molecular weight of one benzyl group (Mw: 90), a peak indicating the sum (M+=624) of the molecular weights of the trimer structure and two benzyl groups, a peak indicating the sum (M+=714) of the molecular weights of the trimer structure and three benzyl groups, a peak indicating the sum (M+=804) of the molecular weights of the trimer structure and four benzyl groups, and a peak indicating the sum (M+=894) of the molecular weights of the trimer structure and five benzyl groups were confirmed.

### Synthetic Example 4

Into a flask equipped with a thermometer, a dropping funnel, a condenser, a distilling column, and a stirrer, 160g (1.0 mol) of 1,5-dihydroxynaphthalene, 108 g (1.0 mol) of benzyl alcohol, and 2.7 g of p-toluenesulfonic acid monohydrate were charged. The mixture was stirred at room temperature while blowing nitrogen. The mixture was then heated to 150° C. and stirred for 4 hours while removing the produced water to outside the system. Upon completion of the reaction, 500 g of methyl isobutyl ketone and 2.8 g of a 20% aqueous solution of sodium hydroxide were added to neutralise the mixture, the water layer was removed by separation, and the residue was washed with 150 g of wafer three times. Methyl isobutyl ketone was removed at a reduced pressure to obtain 250 g of a benzyl-modified naphthalene compound (A-4). The benzyl-modified naphthalene compound (A-4) was black solid, and the hydroxyl equivalent was 170 g/eq.

### Synthetic Example 5

Into a flask equipped with a thermometer, a dropping funnel, a condenser, a distilling column, and a stirrer, 160 g (1.0 mol) of 1,6-dihydroxynaphthalene, 216 g (2.0 mol) of benzyl alcohol, and 3.8 g of p-toluenesulfonic acid monohydrate were charged. The mixture was stirred at room temperature while blowing nitrogen. The mixture was then heated to 150° C. and stirred for 4 hours while removing the produced water to outside the system. Upon completion of the reaction, 680 g of methyl isobutyl ketone and 4.0 g of a 20% aqueous solution of sodium hydroxide were added to neutralize the mixture, the water layer was removed by separation, and the residue was washed with 170 g of wafer three times. Methyl isobutyl ketone was removed at a reduced pressure to obtain 330 g of a benzyl-modified naphthalene compound (A-5). The benzyl-modified naphthalene compound (A-5) was black solid, and the hydroxyl equivalent was 190 g/eq.

### Example 1

Into a flask equipped with a thermometer, a dropping funnel, a condenser, a distilling column, and a stirrer, 203.0 g (number of moles of acid chloride groups: 2.0 mol) of isophthalic acid chloride and 1400 g of toluene were charged, and the system was nitrogen-purged at a reduced pressure to dissolve isophthalic acid chloride. Next, 96.0 g (0.67 mol) of α-naphthol and 240 g (number of moles of phenolic hydroxyl groups: 1.33 mol) of the benzyl-modified naphthalene compound (A-1) were charged, and the system was nitrogen-purged at a reduced pressure to dissolve the compounds. Then 0.70 g of tetrabutylammonium bromide was dissolved, the system was controlled to 60° C. or lower while conducting nitrogen gas purging, and 400 g of a 20% aqueous solution of sodium hydroxide was added dropwise over 3 hours. Under these conditions, stirring was continued for 1.0 hour. Upon completion of the reaction, the mixture was left to stand still to separate, and the water layer was removed. Water was added to the toluene layer in which the reaction product was dissolved, and the mixture was stirred for 15 minutes. Then the mixture was left to stand still to separate, and the water layer was removed. This operation was repeated until the pH of the water layer was 7. Water was removed by decanter dehydration. As a result, active ester resin (B-1) which was in a state of toluene solution with a nonvolatile content of 65% by mass was obtained. The solution viscosity of the toluene solution with a nonvolatile content of 65% by mass was 16000 mPa·S (25QC). The softening point after drying was 156° C.

### Example 2

Into a flask equipped with a thermometer, a dropping funnel, a condenser, a distilling column, and a stirrer, 203.0 g (number of moles of acid chloride groups: 2.0 mol) of isophthalic acid chloride and 1400 g of toluene were charged, and the system was nitrogen-purged at a reduced pressure to dissolve isophthalic acid chloride. Next, 96.0g (0.67 mol) of α-naphthol and 240 g (number of moles of phenolic hydroxyl groups: 1.33 mol) of the benzyl-modified naphthalene compound (A-2) were charged, and the system was nitrogen-purged at a reduced pressure to dissolve the compounds. Then 0.70 g of tetrabutylammonium bromide was dissolved, the system was controlled to 60° C. or lower while conducting nitrogen gas purging, and 400 g of a 20% aqueous solution of sodium hydroxide was added dropwise over 3 hours. Under these conditions, stirring was continued for 1.0 hour. Upon completion of the reaction, the mixture was left to stand still to separate, and the water layer was removed. Water was added to the toluene layer in which the reaction product was dissolved, and the mixture was stirred for 15 minutes. Then the mixture was left to stand still to separate, and the water layer was removed. This operation was repeated until the pH of the water layer was 7. Water was removed by decanter dehydration. As a result, active ester resin (B-2) which was in a state of toluene solution with a nonvolatile content of 65% by mass was obtained. The solution viscosity of the toluene solution with a nonvolatile content of 65% by mass was 15000 mPa·S (25° C.). The softening point after drying was 155° C.

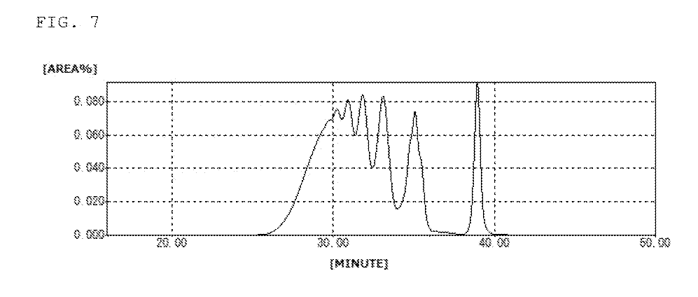

The GPC chart of the active ester resin (B-2) is shown in FIG. 5 and its MALDI-TOF-MS spectrum is shown in FIG. 6.

### Example 3

Into a flask equipped with a thermometer, a dropping funnel, a condenser, a distilling column, and a stirrer, 203.0 g (number of moles of acid chloride groups: 2.0 mol) of isophthalic acid chloride and 1400 g of toluene were charged, and the system was nitrogen-purged at a reduced pressure to dissolve isophthalic acid chloride. Next, 96.0 g (0.67 mol) of α-naphthol and 267 g (number of moles of phenolic hydroxyl groups: 1.33 mol) of the benzyl-modified naphthalene compound (A-3) were charged, and the system was nitrogen-purged at a reduced pressure to dissolve the compounds. Then 0.74 g of tetrabutylammonium bromide was dissolved, the system was controlled to 60° C. or lower while conducting nitrogen gas purging, and 400 g of a 20% aqueous solution of sodium hydroxide was added dropwise over 3 hours. Under these conditions, stirring was continued for 1.0 hour. Upon completion of the reaction, the mixture was left to stand still to separate, and the water layer was removed. Water was added to the toluene layer in which the reaction product was dissolved, and the mixture was stirred for 15 minutes. Then the mixture was left to stand still to separate, and the water layer was removed. This operation was repeated until the pH of the water layer was 7. Water was removed by decanter dehydration. As a result, active ester resin (B-3) which was in a state of toluene solution with a nonvolatile content of 65% by mass was obtained. The solution viscosity of the toluene solution with a nonvolatile content of 65% by mass was 4500 mPa·S (25° C.). The softening point after drying was 148° C.

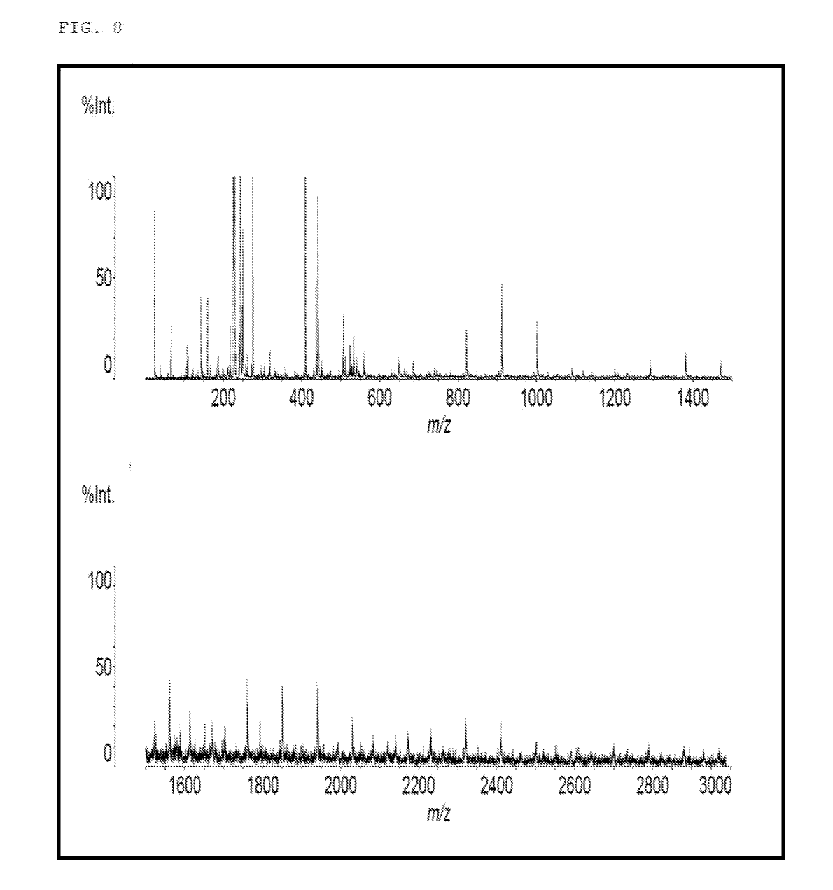

The GPC chart of the active ester resin (B-3) is shown in FIG. 7 and its MALDI-TOF-MS spectrum is shown in FIG. 8.

### Example 4

Into a flask equipped with a thermometer, a dropping funnel, a condenser, a distilling column, and a stirrer, 203.0 g (number of moles of acid chloride groups: 2.0 mol) of isophthalic acid chloride and 1400 g of toluene were charged, and the system was nitrogen-purged at a reduced pressure to dissolve isophthalic acid chloride. Next, 96.0 g (0.67 mol) of α-naphthol and 227 g (number of moles of phenolic hydroxyl groups: 1.33 mol) of the benzyl-modified naphthalene compound (A-4) were charged, and the system was nitrogen-purged at a reduced pressure to dissolve the compounds. Then 0.68 g of tetrabutylammonium bromide was dissolved, the system was controlled to 60° C. or lower while conducting nitrogen gas purging, and 400 g of a 20% aqueous solution of sodium hydroxide was added dropwise over 3 hours. Under these conditions, stirring was continued for 1.0 hour. Upon completion of the reaction, the mixture was left to stand still to separate, and the wafer layer was removed. Water was added to the toluene layer in which the reaction product was dissolved, and the mixture was stirred for 15 minutes. Then the mixture was left to stand still to separate, and the water layer was removed. This operation was repeated until the pH of the water layer was 7. Water was removed by decanter dehydration. As a result, active ester resin (B-4) which was in a state of toluene solution with a nonvolatile content of 65% by mass was obtained. The solution viscosity of the toluene solution with a nonvolatile content of 65% by mass was 14000 mPa·S (25° C.). The softening point after drying was 150° C.

### Example 5

Into a flask equipped with a thermometer, a dropping funnel, a condenser, a distilling column, and a stirrer, 203.0 g (number of moles of acid chloride groups: 2.0 mol) of isophthalic acid chloride and 1400 g of toluene were charged, and the system was nitrogen-purged at a reduced pressure to dissolve isophthalic acid chloride. Next, 96.0 g (0.67 mol) of α-naphthol and 246 g (number of moles of phenolic hydroxyl groups: 1.33 mol) of the benzyl-modified naphthalene compound (A-5) were charged, and the system was nitrogen-purged at a reduced pressure to dissolve the compounds. Then 0.71 g of tetrabutylammonium bromide was dissolved, the system was controlled to 60° C. or lower while conducting nitrogen gas purging, and 400 g of a 20% aqueous solution of sodium hydroxide was added dropwise over 3 hours. Under these conditions, stirring was continued for 1.0 hour. Upon completion of the reaction, the mixture was left to stand still to separate, and the water layer was removed. Water was added to the toluene layer in which the reaction product was dissolved, and the mixture was stirred for 15 minutes. Then the mixture was left to stand still to separate, and the water layer was removed. This operation was repeated until the pH of the water layer was 7. Water was removed by decanter dehydration. As a result, active ester resin (B-5) which was in a state of toluene solution with a nonvolatile content of 65% by mass was obtained. The solution viscosity of the toluene solution with a nonvolatile content of 65% by mass was 4300 mPa·S (25° C.). The softening point after drying was 145° C.

### Comparative Example 1

Into a flask equipped with a thermometer, a dropping funnel, a condenser, a distilling column, and a stirrer, 180 g of the benzyl-modified naphthalene compound (A-1) obtained in Synthetic Example 1 and 480 g of methyl isobutyl ketone (hereinafter referred to as “MIBK”) were charged, and the system was nitrogen-purged at a reduced pressure to dissolve the compound. Then 20.3 g (0.10 mol) of isophthalic acid chloride and 112 g (0.80 mol) of benzoyl chloride were charged, the system was controlled to 60° C. or lower while conducting nitrogen gas purging, and 210 g of a 20% aqueous solution of sodium hydroxide was added dropwise over 3 hours. Under these conditions, stirring was continued for 1.0 hour. Upon completion of the reaction, the mixture was left to stand still to separate, and the wafer layer was removed. Water was added to the MIBK layer in which the reaction product was dissolved, and the mixture was stirred for 15 minutes. Then the mixture was left to stand still to separate, and the water layer was removed. This operation was repeated until the pH of the water layer was 7. Water was removed by decanter dehydration. As a result, active ester resin (B-6) which was in a state of MIBK solution with a nonvolatile content of 65% by mass was obtained. The solution viscosity of the MIBK solution with a nonvolatile content of 65% by mass was 6000 mPa·S (25° C.). The softening point after drying was 150° C.

### Comparative Example 2

The same procedure as in Comparative Example 1 (112 g (0.80 mol) of benzoyl chloride was used) was conducted except that the benzyl-modified naphthalene compound (A-1) was changed to 105 g of a phenol novolac resin (“PHENOLITE TD-2090” produced by DIC corporation, hydroxyl equivalent: 105 g/eq, softening point: 120° C.). As a result, an active ester resin (B-7) in a state of MIBK solution with a nonvolatile content of 65% by mass was obtained. The solution viscosity of the MIBK solution with a nonvolatile content of 65% by mass was 9000 mPa·S (25° C.). The softening point after drying was 170° C.

### Examples 6 to 10 and Comparative Examples 3 and 4

### Preparation of Thermosetting Resin Composition and Evaluation of Physical Properties

In accordance to the formulations described in Table 1 below, a cresol novolac epoxy resin (“N-680” produced by DIC Corporation, epoxy equivalent: 214 g/eq) serving as an epoxy resin and a corresponding one of (B-1) to (B-7) serving as a curing agent were added, and 0.5 phr of dimethylaminopyridine was further added as a cure accelerator. Then methyl ethyl ketone was added so that the nonvolatile (N.V.) content of each composition was 58% by mass ultimately so as to prepare a thermosetting resin composition.

Next, the composition was cured under the following conditions to form a multilayer board. The heat resistance, dielectric properties, and flame retardancy of the multilayer board were evaluated by the following procedures. The results are shown in Table 1.

### <Conditions for Preparing Multilayer Board>

Substrate: glass cloth “#2116” (210×280 mm) produced by Nitto Boseki Co., Ltd.
Number of plies: 6 Condition of preparing prepreg: 160° C.
Curing condition: 200° C., 40 kg/cm² for 1.5 hours, thickness after forming: 0.8 mm

### <Heat Resistance (Glass Transition Temperature)>

The cured product having a thickness of 0.8 mm was cut into a test specimen having a width of 5 mm and a length of 54 mm. The test specimen was analyzed with a viscoelasticity measurement instrument (DMA: viscoelasticity measurement instrument “RSA II” produced by Rheometries, Inc., rectangular tension method: frequency 1 Hz, heating rate 3° C./min), and the temperature at which the change in elastic modulus was largest (the change in tan δ was largest) was assumed to be the glass transition temperature.

### <Measurement of Dielectric Constant and Loss Tangent>

The dielectric constant at 1 GHz and the loss tangent of the test specimen after it was absolutely dried and stored for 24 hours in a 23° C., 50% humidity room were measured in accordance with JIS-C-6481 by using an impedance material analyzer, “HP4291B” produced by Agilent Technologies.

### <Flame Retardancy>

A cured product having a thickness of 0.8 mm was cut into a specimen having a width of 12.7 mm and a length of 127 mm. A flammability test was conducted in accordance with the UL-94 test method by using five test specimens.

### <Thermal Decomposition Resistance>

A test specimen cut to a size at which the mass was 6 mg was held at 150° C. for 15 minutes. The temperature was increased at 5° C. per minute under a nitrogen gas flow condition, and the temperature at which the mass decreased by 5% was measured with a TG-DTA meter (“TGA/DSC1” produced by METTLER TOLEDO).

TABLE 1

| | | Example | Example | Example | Example | Example | Comparative | Comparative |
|---|---|---|---|---|---|---|---|---|
| | | 6 | 7 | 8 | 9 | 10 | Example 3 | Example 4 |
| Epoxy resin | N-680 | 47.9 | 47.9 | 46.5 | 48.6 | 47.2 | 43.7 | 51.6 |
| Active ester resin | B-1 | 52.1 | | | | | | |
| | B-2 | | 52.1 | | | | | |
| | B-3 | | | 53.5 | | | | |
| | B-4 | | | | 51.4 | | | |
| | B-5 | | | | | 52.8 | | |
| | B-6 | | | | | | 56.3 | |
| | B-7 | | | | | | | 48.4 |
| Heat resistance | | | | | | | | |
| (° C.) | | 198 | 196 | 190 | 195 | 188 | 180 | 165 |
| Dielectric | | | | | | | | |
| constant | | 3.5 | 3.5 | 3.5 | 3.6 | 3.6 | 3.8 | 4.0 |
| [1 GHz] | | | | | | | | |
| Loss tangent | | 0.005 | 0.005 | 0.006 | 0.006 | 0.010 | 0.009 | 0.012 |
| [10 GHz] | | | | | | | | |
| Flammability test | | V-1 | V-1 | V-1 | V-1 | V-1 | V-1 | Burned |
| Class | | | | | | | | |
| *1 | | 18 | 19 | 25 | 25 | 28 | 30 | — |
| *2 | | 70 | 75 | 85 | 90 | 94 | 124 | — |
| Thermal | | 412 | 410 | 405 | 406 | 401 | 379 | 370 |
| decomposition | | | | | | | | |
| resistance | | | | | | | | |
| [Td5] (° C.) | | | | | | | | |

Footnotes for Table 1
*1: A total burning time (sec) of five test specimens
*2: The maximum burning time (sec) in one flame application

1-13. (canceled)

14. An active ester resin comprising a resin structure that has a structural segment represented by formula (I) below and monovalent aryloxy groups at both terminals: 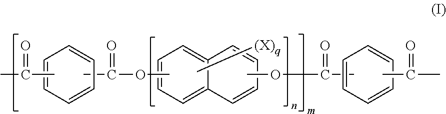
(in formula (I), X each independently represent a group represented by formula (H) below: 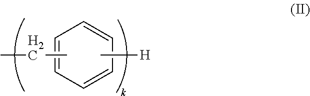
or a group represented by formula (III) below: 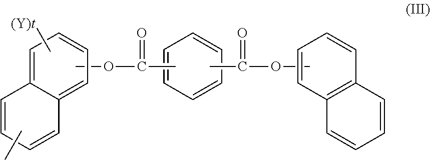
where m represents an integer of 1 to 6, n each independently represent an integer of 1 to 5, and q each independently represent an integer of 0 to 6,
in formula (IT), k each independently represent an integer of 1 to 5, and
in formula (III), Y represents a group represented by formula (II) above (where k each independently represent an integer of 1 to 5), and t each independently represent an integer of 0 to 5).

15. A thermosetting resin composition comprising the active ester resin according to claim 14 and an epoxy resin as essential components.

16. The thermosetting resin composition according to claim 15, further comprising a cure accelerator.

17. A cured product of the thermosetting resin composition according to claim 15.

18. A cured product of the thermosetting resin composition according to claim 16.
